(19) United States
(12) Patent Application Publication
(10) Pub. No.: US 2017/0288152 A1
(43) Pub. Date: Oct. 5, 2017

(54) COMPOSITION FOR FORMING ORGANIC SEMICONDUCTOR FILM, ORGANIC SEMICONDUCTOR FILM, MANUFACTURING METHOD THEREOF, ORGANIC SEMICONDUCTOR ELEMENT, AND MANUFACTURING METHOD THEREOF

(71) Applicant: FUJIFILM CORPORATION, Tokyo (JP)

(72) Inventors: Toshihiro KARIYA, Kanagawa (JP); Tetsu KITAMURA, Kanagawa (JP)

(21) Appl. No.: 15/623,381

(22) Filed: Jun. 15, 2017

Related U.S. Application Data
(63) Continuation of application No. PCT/JP2016/053222, filed on Feb. 3, 2016.

(30) Foreign Application Priority Data
Feb. 12, 2015 (JP) 2015-025357
Mar. 27, 2015 (JP) 2015-066072

(51) Int. Cl. H01L 51/00

(52) U.S. Cl. CPC H01L 51/0074; H01L 51/0068; H01L 51/0094; H01L 51/0055; H01L 51/0071; H01L 51/0073; H01L 51/0035; H01L 51/004; H01L 51/0043; H01L 51/0005; H01L 51/0007; H01L 51/0545

(57) ABSTRACT

A composition for forming an organic semiconductor film includes an organic semiconductor represented by Formula A-1, a polymer, a solvent having a boiling point of 150° C. or higher and an SP value of 18 to 23, and a silicone compound having a structure represented by Formula D-1.

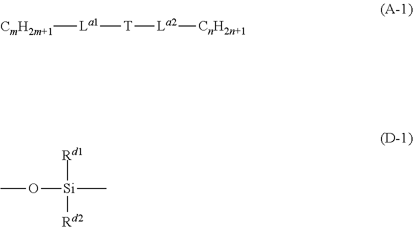

### CROSS-REFERENCE TO RELATED APPLICATIONS

This application is a continuation application of International Application No. PCT/JP2016/053222, filed Feb. 3, 2016, the disclosure of which is incorporated herein by reference in its entirety. Further, this application claims priority from Japanese Patent Application No. 2015-025357, filed Feb. 12, 2015, and Japanese Patent Application No. 2015-066072, filed Mar. 27, 2015, the disclosures of which are incorporated herein by reference in their entirety.

### BACKGROUND OF THE INVENTION

### 1. Field of the Invention

The present invention relates to a composition for forming an organic semiconductor film, an organic semiconductor film, a manufacturing method thereof, an organic semiconductor element, and a manufacturing method thereof

### 2. Description of the Related Art

An organic transistor having an organic semiconductor film (organic semiconductor layer) is used in a field effect transistor (FET) used in a liquid crystal display or an organic EL display, RFID (RF tag), and the like, because lightening of weight, cost reduction, and flexibilization can be achieved.

As the organic semiconductor in the related art, those disclosed in JP2014-22498A and WO2014/061465A are known.

### SUMMARY OF THE INVENTION

An object to be achieved by the present invention is to provide a composition for forming an organic semiconductor film in which mobility of an obtained organic semiconductor element is high and variation in mobility is suppressed. Another object to be achieved by the present invention is to provide an organic semiconductor film using the composition for forming an organic semiconductor film, a manufacturing method thereof, an organic semiconductor element, and a manufacturing method thereof.

The objects of the present invention were solved by the means described in <1>, <15> to <17>, or <19> below. <2> to <14> and <18> which are preferable embodiments are also described below.

<1> A composition for forming an organic semiconductor film, comprising: an organic semiconductor represented by Formula A-1, as Component A; a polymer as Component B; a solvent having a boiling point of 150° C. or higher and an SP value of 18 to 23 as Component C; and a silicone compound having a structure represented by Formula D-1, as Component D,

CₘH₂ₘ₊₁-L^{a1}-T-L^{a2}-CₙH₂ₙ₊₁ (A-1)

in Formula A-1, T represents an aromatic hydrocarbon group or a hetero aromatic group which has a fused ring structure of three rings to seven rings, L^{a1} and L^{a2} each independently represent a single bond, a phenylene group, or a thienylene group, and m and n each independently represent an integer of 1 to 20, and m≠n, and

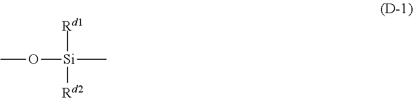

in Formula D-1, R^{d1} and R^{d2} each independently represent a monovalent hydrocarbon group not including an ether bond.

<2> The composition for forming an organic semiconductor film according to <1>, in which the compound represented by Formula A-1 is a compound represented by Formula A-2,

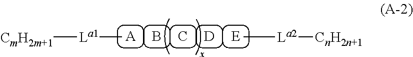

in Formula A-2, Rings A to E each independently represent a benzene ring or an aromatic hetero ring, L^{a1} and L^{a2} each independently represent a single bond, a phenylene group, or a thienylene group, x represents an integer of 0 to 3, m and n each independently represent an integer of 1 to 20, and m≠n.

<3> The composition for forming an organic semiconductor film according to <2>, in which in Formula A-2, symmetry of a fused ring structure formed of Rings A to E is C₂, C₂ᵥ, or C₂ₕ.

<4> The composition for forming an organic semiconductor film according to <2> or <3>, in which, in Formula A-2, Rings A to E each independently represent a benzene ring or a thiophene ring.

<5> The composition for forming an organic semiconductor film according to any one of <2> to <4>, in which, in Formula A-2, Rings A and E are thiophene rings.

<6> The composition for forming an organic semiconductor film according to any one of <2> to <5>, in which, in Formula A-2, x is 1 or 2.

<7> The composition for forming an organic semiconductor film according to any one of <1> to <6>, in which, in Formula A-1 or A-2, 1≦|m−n|≦4.

<8> The composition for forming an organic semiconductor film according to any one of <1> to <7>, in which, in Formula A-1 or A-2, |m−n|=1.

<9> The composition for forming an organic semiconductor film according to any one of <1> to <8>, in which, in Formula D-1, at least one of R^{d1} or R^{d2} is an alkyl group having 2 to 18 carbon atoms or an alkenyl group having 2 to 18 carbon atoms.

<10> The composition for forming an organic semiconductor film according to any one of <1> to <9>, in which in Formula D-1, at least one of R^{d1} or R^{d2} is an aralkyl group.

<11> The composition for forming an organic semiconductor film according to any one of <1> to <10>, in which Component C contains a halogen atom.

<12> The composition for forming an organic semiconductor film according to any one of <1> to <11>, in which Component C is an aromatic solvent.

<13> The composition for forming an organic semiconductor film according to any one of <1> to <12>, in which viscosity at 25° C. is 5 mPa·s to 40 mPa·s.

<14> The composition for forming an organic semiconductor film according to any one of <1> to <13>, which is used for ink jet printing and/or flexographic printing.

<15> A method of manufacturing an organic semiconductor film, comprising: an applying step of applying the composition for forming an organic semiconductor film according to any one of <1> to <14> on a substrate; and a drying step.

<16> An organic semiconductor film obtained by the method according to <15>.

<17> A method of manufacturing an organic semiconductor element, comprising: an applying step of applying the composition for forming an organic semiconductor film according to any one of <1> to <14> on a substrate; and a drying step.

<18> The method of manufacturing an organic semiconductor element according to <17>, in which the applying step is performed by ink jet printing or flexographic printing.

<19> An organic semiconductor element obtained by the method according to <17> or <18>.

According to the present invention, it is possible to provide a composition for forming an organic semiconductor film in which mobility of an obtained organic semiconductor element is high and variation in mobility is suppressed. According to the present invention, it is possible to provide an organic semiconductor film using the composition for forming an organic semiconductor film, a manufacturing method thereof, an organic semiconductor element, and a manufacturing method thereof.

### BRIEF DESCRIPTION OF THE DRAWINGS

FIG. 1 is a schematic cross-sectional view of an aspect of an organic semiconductor element of the present invention.

FIG. 2 is a schematic cross-sectional view of another aspect of the organic semiconductor element of the present invention.

FIG. 3 is a plan view of a metal mask used in an example.

### DESCRIPTION OF THE PREFERRED EMBODIMENTS

Hereinafter, the contents of the present invention will be specifically described. The constituents in the following description will be explained based on typical embodiments of the present invention, but the present invention is not limited to the embodiments. In the specification of the present application, “to” is used to mean that the numerical values listed before and after “to” are a lower limit and an upper limit respectively. Furthermore, in the present invention, an organic EL element refers to an organic electroluminescence element.

In the present specification, in a case where there is no description regarding whether a group (atomic group) is substituted or unsubstituted, the group includes both of a group having a substituent and a group not having a substituent. For example, an “alkyl group” includes not only an alkyl group not having a substituent (unsubstituted alkyl group) but also an alkyl group having a substituent (substituted alkyl group).

In the present specification, in some cases, a chemical structural formula is described as a simplified structural formula in which a hydrogen atom is omitted.

In the present invention, “mass %” and “weight %” have the same definition, and “part by mass” and “part by weight” have the same definition.

In the present invention, a combination of two or more preferred aspects is more preferable.

(Composition for Forming an Organic Semiconductor Film)

The composition for forming an organic semiconductor film according to the present invention contains an organic semiconductor represented by Formula A-1, as Component A, a polymer as Component B, a solvent having a boiling point of 150° C. or higher and an SP value of 18 to 23 as Component C, and a silicone compound having a structure represented by Formula D-1, as Component D.

The present inventors diligently conducted research and found that, if the composition for forming an organic semiconductor film containing Components A to D is employed, mobility of an obtained organic semiconductor film or an organic semiconductor element is high, and variation in mobility is suppressed, so as to complete the present invention.

A detailed mechanism of exhibiting effects is not clear, but it is assumed as follows. It is found that, as in Component A, an organic semiconductor having an asymmetric side chain is effective for improving solubility compared with an organic semiconductor having a symmetric side chain, but mobility decreases, and variation in mobility occurs. It is assumed that this is because, if an organic semiconductor has an asymmetric side chain, crystallinity of the obtained organic semiconductor film decreases, or a crystal structure becomes unstable.

The present inventors diligently conducted research and found that, if Components B to D and Component A are combined to be used, the objects described above can be achieved. If Components B to D are used, wettability to a substrate is maintained, and flow of liquid is suppressed, an organic semiconductor crystal growth is stabilized, and thus it is possible to obtain an organic semiconductor film and an organic semiconductor element in which mobility is high and variation in mobility is suppressed even in an organic semiconductor having an asymmetric side chain.

Hereinafter, respective components used in the composition for forming an organic semiconductor film according to the present invention are described.

Component A: Compound Represented by Formula A-1

The composition for forming an organic semiconductor film according to the present invention contains a compound (hereinafter, referred to as a “specific compound”) represented by Formula A-1, as Component A.

CₘH₂ₘ₊₁-L^{a1}-T-L^{a2}-CₙH₂ₙ₊₁ (A-1)

In Formula A-1, T represents an aromatic hydrocarbon group or a hetero aromatic group which has a fused ring structure of three rings to seven rings, L^{a1} and L^{a2} each independently represent a single bond, a phenylene group, or a thienylene group, m and n each independently represent an integer of 1 to 20, and m≠n.

Component A can be suitably used in an organic semiconductor element, an organic semiconductor film, and a composition for forming an organic semiconductor film.

Component A is a compound in which alkyl groups having different numbers of carbon atoms (CₘH₂ₘ₊₁ and CₙH₂ₙ₊₁, m≠n) that are bonded to organic semiconductor mother nucleus (T) via linking groups (L^{a1}, L^{a2}), if necessary. The linking group is a phenylene group or a thienylene group.

In Formula A-1, T represents an aromatic hydrocarbon group or a hetero aromatic group (aromatic heterocyclic group) which has a fused ring structure of three rings to seven rings. T is a group that can be obtained by condensing three to seven aromatic rings, and aromaticity is exhibited. Examples of the aromatic ring include an aromatic hydrocarbon ring (for example, a benzene ring), and an aromatic hetero ring (for example, a thiophene ring, a furan ring, a pyrrole ring, a selenophene ring, and an imidazole ring).

T has three to seven rings, preferably has four to six rings, and more preferably has five or six rings.

At least one of the aromatic rings included in T is preferably an aromatic hetero ring, and more preferably includes at least one atom selected from the group consisting of a sulfur atom, a nitrogen atom, a selenium atom, and an oxygen atom, as a hetero atom. In view of mobility as an organic semiconductor, it is more preferable that the two to six rings have the hetero atoms, and it is even more preferable that two to four rings have the hetero atoms.

In view of mobility as an organic semiconductor, the aromatic hetero ring preferably has one hetero atom.

In view of mobility as an organic semiconductor, T preferably has at least one structure selected from the group consisting of a furan ring structure, a thiophene ring structure, and a selenophene ring structure, more preferably has at least a thiophene ring structure or a selenophene ring structure, and even more preferably has at least a thiophene ring structure. It is particularly preferable that all of the hetero ring structures included in T are thiophene ring structures.

In the compound represented by Formula A-1, the group represented by T is included, but it is preferable that this group is included as a main component. Here, the main component means that a content of a molecular weight of a fused polycyclic aromatic group is 30% or greater and preferably 40% or greater with respect to a total molecular weight of the compound represented by Formula A-1. The upper limit is not particularly limited, but in view of solubility, the upper limit is preferably 80% or lower.

In Formula A-1, T is preferably a structure in which an aromatic hetero ring and/or a benzene ring is fused in a linear shape (including a straight line and a zigzag shape), T more preferably includes an acene structure, a phenacene structure, or a heteroacene structure having a fused ring structure of three to seven rings. Here, acene is a structure in which benzene rings are fused in a linear shape such that an angle formed by benzene rings with each other is 180°, and specific examples thereof include naphthalene, anthracene, tetracene, pentacene, hexacene, and heptacene. Phenacene is a structure in which benzene rings are fused in a zigzag shape, and specific examples thereof include phenanthrene, chrysene, and picene. Heteroacene means a structure in which a portion of benzene rings of acene or phene is substituted with an aromatic hetero ring (for example, a furan ring, a thiophene ring, and a pyrrole ring). Phene is a structure in which benzene rings are fused in a shape including a zigzag shape, and includes phenacene in which all benzene rings have a zigzag shape. Examples of compounds that are included in phene and that are not included in phenacene include benz[a]anthracene, benzo[c]phenanthrene, dibenz[a,h]anthracene, dibenz[a,j]anthracene, dibenzo[c,g]phenanthrene, and pentaphene.

The specific compound, T which is an organic semiconductor mother nucleus preferably includes a heteroacene skeleton which is a structure in which aromatic hetero rings and/or benzene rings are fused in a linear shape, more preferably a thienoacene structure which is a structure in which a thiophene ring and/or a benzene ring is fused in a linear shape, and even more preferably a thienoacene structure having three to seven fused rings. In the shape above, an organic semiconductor layer or film with higher mobility can be obtained.

With respect to the fused polycyclic aromatic group, in view of mobility of the organic semiconductor, the number of thiophene rings in the fused polycyclic aromatic group is preferably 2 to 7, more preferably 3 to 7, and even more preferably 3 to 5.

The aromatic hydrocarbon group or a hetero aromatic group which has a fused ring structure included in T may have a substituent.

Examples of the substituent include a halogen atom, an alkyl group (including a cycloalkyl group, a bicycloalkyl group, and a tricycloalkyl group), an alkenyl group, an alkynyl group, an aryl group, a heterocyclic group, a cyano group, a hydroxy group, a nitro group, a carboxy group, an alkoxy group, an aryloxy group, a silyloxy group, a heterocyclic oxy group, an acyloxy group, a carbamoyloxy group, an alkoxycarbonyloxy group, an aryloxycarbonyloxy group, an amino group (including an anilino group), an ammonio group, an acylamino group, an aminocarbonylamino group, an alkoxycarbonylamino group, an aryloxycarbonylamino group, a sulfamoylamino group, alkyl and arylsulfonylamino groups, a mercapto group, an alkylthio group, an arylthio group, a heterocyclic thio group, a sulfamoyl group, a sulfo group, alkyl and arylsulfinyl groups, alkyl and arylsulfonyl groups, an acyl group, an aryloxycarbonyl group, an alkoxycarbonyl group, a carbamoyl group, aryl and heterocyclic azo groups, an imide group, a phosphino group, a phosphinyl group, a phosphinyloxy group, a phosphinylamino group, a phosphono group, a silyl group (a trialkylsilyl group and the like), a hydrazino group, an ureido group, a boronic acid group (—B(OH)₂), a phosphato group (—OPO(OH)₂), a sulfato group (—OSO₃H), and other well-known substituents. The substituent may be further substituted with a substituent.

Among these, as the substituent, a halogen atom, an alkyl group, an alkenyl group, an alkoxy group, an alkylthio group, and an aryl group are preferable, a fluorine atom, a substituted or unsubstituted alkyl group having 1 to 3 carbon atoms, a substituted or unsubstituted alkoxy group having 1 or 2 carbon atoms, a substituted or unsubstituted methylthio group, and a phenyl group are more preferable, a fluorine atom, a substituted or unsubstituted alkyl group having 1 to 3 carbon atoms, a substituted or unsubstituted alkoxy group having 1 or 2 carbon atoms, and a substituted or unsubstituted methylthio group are particularly preferable.

Specific examples of the organic semiconductor mother nucleus represented by T in Formula A-1 preferably include a fused polycyclic aromatic group provided below. With respect to these fused polycyclic aromatic group, the substituent may be bonded to an aromatic hydrocarbon ring and/or an aromatic hetero ring, in addition to -L^{a1}-CₘH₂ₘ₊₁ and -L^{a2}-CₙH₂ₙ₊₁.

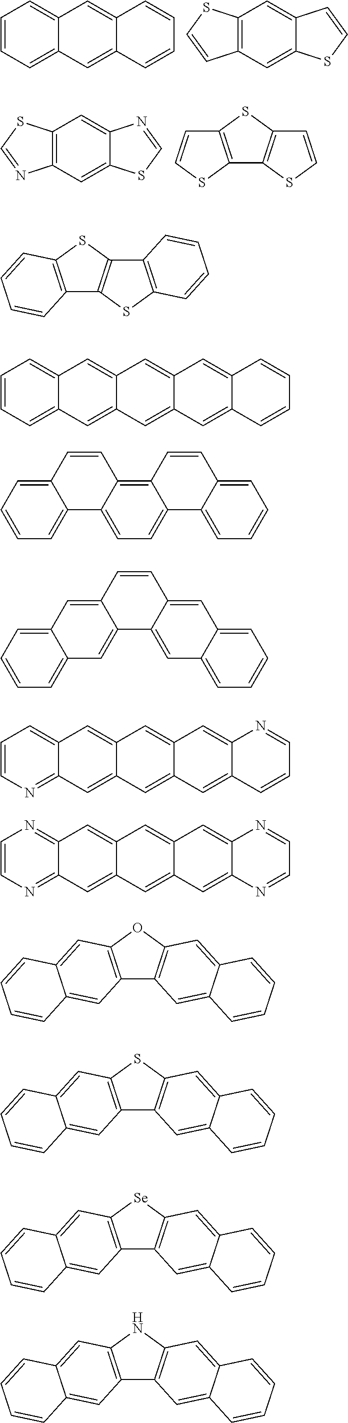

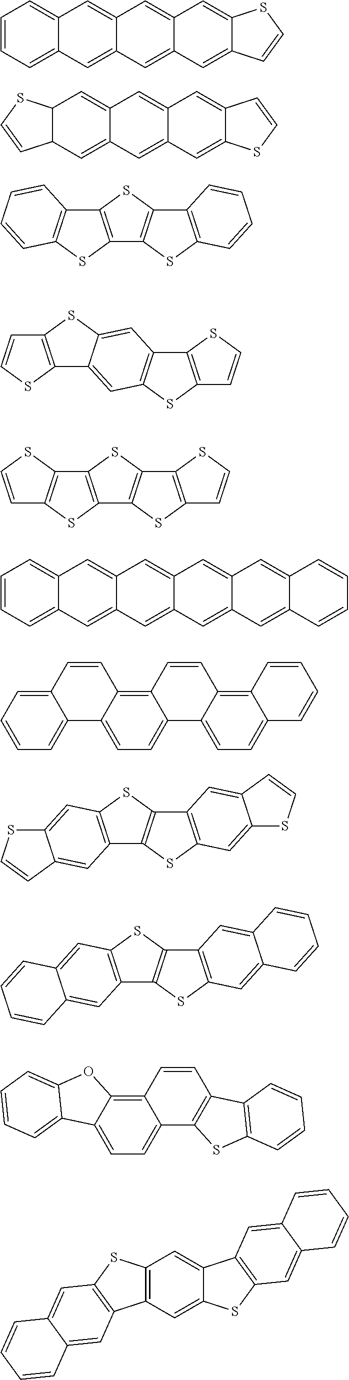

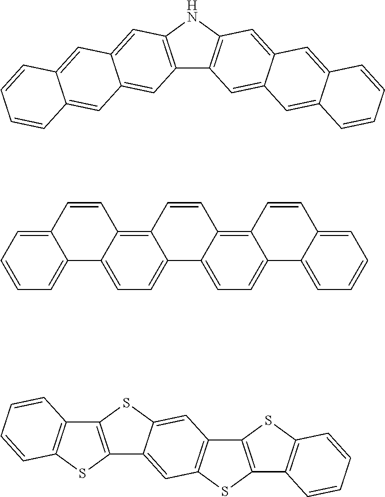

Among the specific examples, a structure in which thiophene rings are fused or a structure in which thiophene rings and benzene rings are fused are thioacene structures.

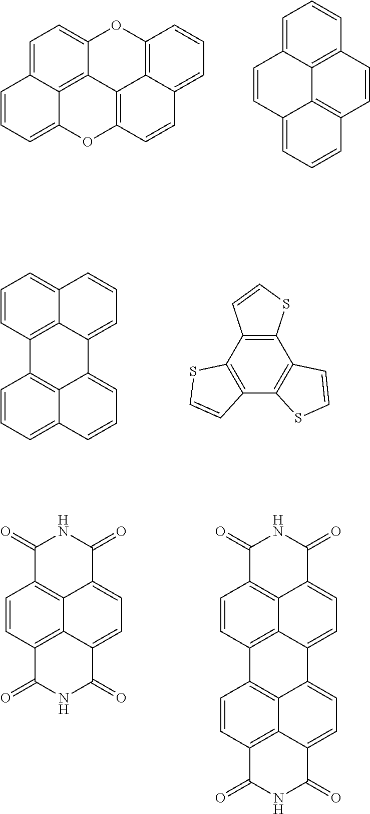

In Formula A-1, L^{a1} and L^{a2} each independently represent a single bond, a phenylene group, or a thienylene group. Here, the thienylene group refers to a group obtained by removing two hydrogen atoms from thiophene. The phenylene group is preferably bonded to T and an alkylene group at a para position. The thienylene group is preferably bonded to T and an alkylene group at the second to fifth positions.

In Formula A-1, m and n each independently represent an integer of 1 to 20. An integer of 2 to 16 is preferable, and an integer of 3 to 12 is more preferable.

In Formula A-1, m≠n is satisfied. That is, CₘH₂ₘ₊₁and CₙH₂ₙ₊₁ are alkyl group having different numbers of carbon atoms (having different chain lengths). |m−n| which is an absolute value of a difference between m and n is preferably 1 to 6, more preferably 1 to 4, even more preferably 1 to 3, and particularly preferably 1 or 2, and most preferably 1. |m−n| is preferably in the range described above, since mobility is excellent and variation in mobility is further suppressed.

Component A is preferably a compound represented by Formula A-2.

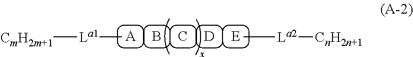

In Formula A-2, Rings A to E each independently represent a benzene ring or an aromatic hetero ring, L^{a1} and L^{a2} each independently represent a single bond, a phenylene group, or a thienylene group, x represents an integer of 0 to 3, m and n each independently represent an integer of 1 to 20, and m≠n.

In Formula A-2, Rings A to E each independently represent a benzene ring or a thiophene ring. Two to four of Rings A to E are preferably thiophene rings.

x represents an integer of 0 to 3. That is, Rings A to E has a fused ring structure of four rings to a fused ring structure of seven rings. x is preferably 1 to 3 and more preferably 1 or 2. If x is in the range described above, mobility becomes excellent.

In a case where x represents 2 or 3, a plurality of Rings C may represent the same rings or different rings.

In Formula A-2, L^{a1}-CₘH₂ₘ₊₁ is substituted with Ring A at a terminal of a fused polycyclic aromatic group constituted with Rings A to E. -L^{a2}-CₙH₂ₙ₊₁ may be substituted with Ring E existing at the other terminal.

In Formula A-2, a fused polycyclic aromatic group constituted with Rings A to E may have a substituent, and examples of the substituent include an alkyl group, an alkenyl group, an alkynyl group, an aromatic hydrocarbon group, an aromatic heterocyclic group, or a fluorine atom. In a case where an alkyl group is included, the alkyl group may be substituted with a group other than Rings A and E. The alkyl group may have any one of a linear shape, a branched shape, and a cyclic shape, is preferably a linear shape, preferably has 1 to 20 carbon atoms, more preferably has 1 to 12 carbon atoms, and even more preferably has 1 to 8 carbon atoms. The alkenyl group preferably has 2 to 20 carbon atoms, more preferably has 2 to 12 carbon atoms, and even more preferably has 2 to 8 carbon atoms. An alkynyl group preferably has 2 to 20 carbon atoms, more preferably has 2 to 12 carbon atoms, and even more preferably has 2 to 8 carbon atoms. An alkenyl group and an alkynyl group may have any one of a linear shape, a branched shape, and a cyclic shape, and is preferably a linear shape. The aromatic hydrocarbon group preferably has 6 to 30 carbon atoms, more preferably has 6 to 20 carbon atoms, even more preferably has 6 to 10 carbon atoms, and particularly preferably a phenyl group. The aromatic heterocyclic group preferably has at least one hetero atom selected from the group consisting of a sulfur atom, an oxygen atom, a nitrogen atom, and a selenium atom, as a hetero atom, and more preferably has a hetero atom selected the group consisting of a sulfur atom, a nitrogen atom, or an oxygen atom. The aromatic heterocyclic group may be a single ring or a polycyclic ring, is preferably a 5-membered ring to a 30-membered ring, more preferably a 5-membered ring to a 20-membered ring, and even more preferably a 5-membered ring to a 10-membered ring.

In the compound represented by Formula A-2, Rings A and E are preferably thiophene rings, and/or L^{a1} or L^{a2} are thienylene rings. That is, an alkyl group is preferably substituted with a thiophene ring.

In Formula A-2, symmetry of a fused ring structure formed with Rings A to E is preferably C₂, C₂ᵥ, or C₂ₕ. If the symmetry is C₂, C₂ᵥ, or C₂ₕ, a regular crystal structure can be easily formed, and high mobility can be easily exhibited.

With respect to the symmetry of the fused ring structure, “Molecular symmetry and group theory” (Masao Nakazaki, Tokyo Kagaku Dojin Co., Ltd.) is referred to.

In Formula A-2, m and n each independently represent an integer of 1 to 20, m≠n is satisfied. The preferable ranges of m, n, and −m−n| are the same as the preferable ranges of m, n, and |m−n| in Formula A-1.

Component A is exemplified below, but the present invention is not limited to these examples.

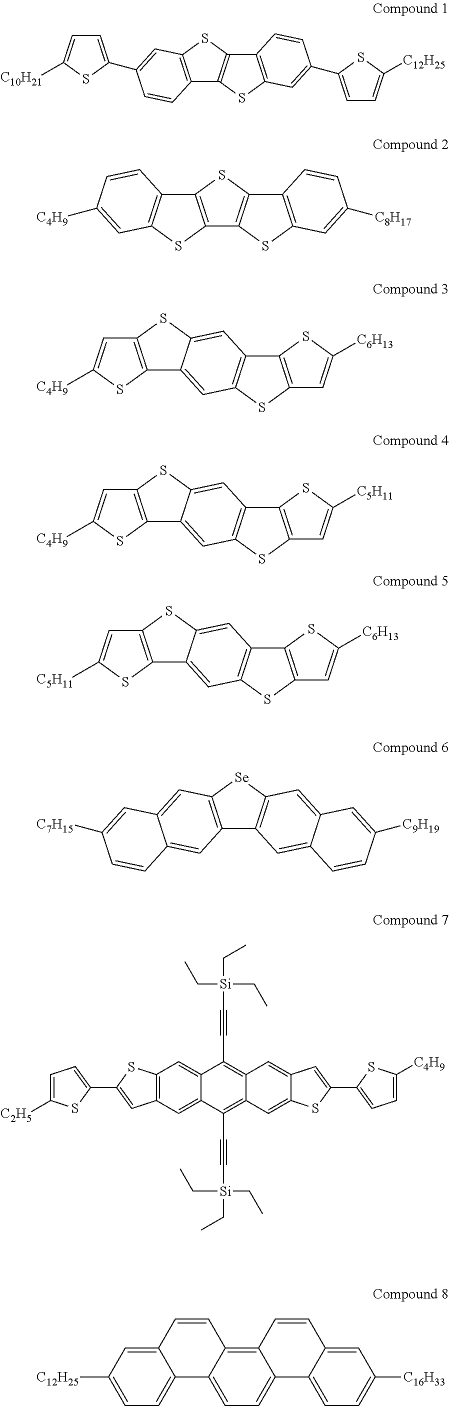

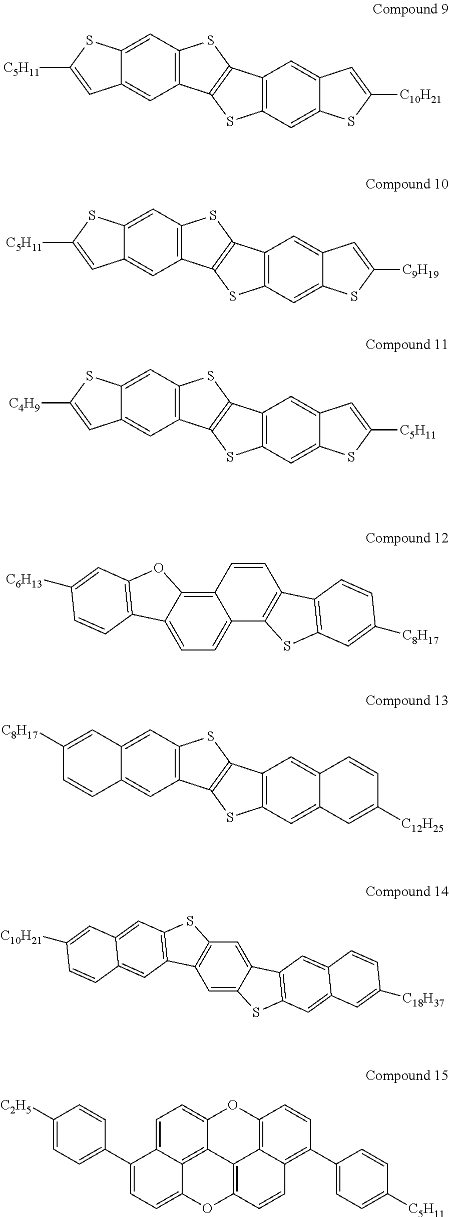

Among these, Compounds 1 to 14 are preferable, Compounds 1 to 7, 9 to 11, 13, and 14 are more preferable, Compounds 1 to 5, 9 to 11, 13, and 14 are even more preferable, Compounds 3 to 5, and 9 to 11 are particularly preferable, and Compound 4, 5, and 11 are most preferable.

A molecular weight of Component A is not particularly limited, but a molecular weight is preferably 1,500 or less, more preferably 1,000 or less, and even more preferably 800 or less. If the molecular weight is the upper limit value or less, solubility to the solvent can be increased. Meanwhile, in view of film stability of a thin film, a molecular weight is preferably 400 or greater, more preferably 450 or greater, and even more preferably 500 or greater.

Component A may be used singly or two or more types thereof may be used in combination.

The manufacturing method of Component A is not particularly limited, and Component A can be synthesized with reference to the well-known methods. Specifically, methods disclosed in JP2011-32268A, JP2009-54810A, JP2011-526588A, JP2012-209329A, Scientific Report, 2014, 4, 5048., JP2013-540697A, JP2009-218333A, US2008/0142792A, WO2014/156773A, WO2010/098372A, Adv. Mater., 2014, 26, 4546. and JP2010-6794A can be referred to.

In the composition for forming an organic semiconductor film according to the present invention, a content of Component A is preferably 5 to 98 mass %, more preferably 10 to 95 mass %, and even more preferably 20 to 80 mass % with reference to the total solid content. The content of Component A is preferably 80 to 99 mass % and more preferably 85 to 98 mass % with respect to a total solid content excluding the following polymer.

The content of Component A of the composition for forming an organic semiconductor film according to the present invention is preferably 0.7 mass % or greater and less than 15 mass %. If the content of Component A is 0.7 mass % or greater, it is possible to obtain an organic semiconductor film and an organic semiconductor element in which mobility is high and variation in mobility is suppressed. Meanwhile, a content of Component A is 15 mass % or less, the composition for forming an organic semiconductor film can be suitably used for ink jet printing and/or flexographic printing.

The content of Component A in the composition for forming an organic semiconductor film is preferably 1.0 to 10 mass %, more preferably 1.25 to 10 mass %, and even more preferably 1.5 to 10 mass %.

The composition for forming an organic semiconductor film according to the present invention may further contain an organic semiconductor that does not correspond to Component A, a content of Component A is preferably 50 mass % or greater, more preferably 70 mass % or greater, and even more preferably 90 mass % or greater, with respect to a total content of the organic semiconductor. The total amount of the organic semiconductor contained in the composition for forming an organic semiconductor film according to the present invention is particularly preferably Component A.

Component B: Polymer

The composition for forming an organic semiconductor film according to the present invention contains a polymer as Component B.

The organic semiconductor film and the organic semiconductor element according to the present invention is an organic semiconductor element having a layer containing the organic semiconductor and a layer including a polymer.

The types of the polymer are not particularly limited, and well-known polymers can be used.

Examples of the polymer includes insulating polymers such as polystyrene, polycarbonate, polyarylate, polyester, polyamide, polyimide, polyurethane, polysiloxane, polysulfone, polymethyl methacrylate, polymethyl acrylate, cellulose, polyethylene, and polypropylene, and copolymers thereof, a semiconductor polymer such as polysilane, polycarbazole, polyarylamine, polyfluorene, polythiophene, polypyrrole, polyaniline, polyparaphenylenevinylene, polyacene, and polyheteroacene, and copolymers thereof, and rubber, and a thermoplastic elastomer.

Among these, as the polymer, a polymer compound (a polymer having a monomer unit having a benzene ring group) having a benzene ring is preferable. The content of the monomer unit having a benzene ring group is not particularly limited. However, the content is preferably 50 mol % or greater, more preferably 70 mol % or greater, and even more preferably 90 mol % or greater with respect to the entire monomer unit. The upper limit is not particularly limited, but examples of the upper limit include 100 mol %.

Examples of the polymer include polystyrene, poly(α-methylstyrene), polyvinyl cinnamate, poly(4-vinylphenyl), poly(4-methyl styrene), poly[bis(4-phenyl) (2,4,6-trimethylphenyl)amine], and poly[2,6-(4,4-bis(2-ethylhexyl)-4H cyclopenta[2,1-b;3,4-b′]dithiophene)-alt-4,7-(2,1,3-benzothiadiazole)], and polystyrene poly(α-methylstyrene) are particularly preferable, and poly(α-methylstyrene) is most preferable.

According to the present invention, the surface energy of Component B is preferably 20 mN/m² to 45 mN/m², more preferably 25 mN/m² to 45 mN/m², and even more preferably 30 mN/m² to 40 mN/m².

It is preferable that the surface energy of Component B is in the range described above, since variation in mobility is more suppressed.

The surface energy is referred to as surface free energy, and the surface energy of the polymer according to the present invention means a value that can be obtained from below.

First, a polymer 1% solution was added dropwise to a glass substrate, and coating is performed by spin coating (1,000 rpm, 120 seconds), and heating is performed at 150° C./30 minutes, so as to obtain a polymer film.

Subsequently, a contact angle of water and diiodomethane with respect to the surface of the polymer film is measured as contact angle measurement (for example, contact angle meter DM-501 manufactured by Kyowa Interface Science Co., Ltd.).

The obtained contact angle and the obtained surface tension value of the liquid are used so as to obtain a surface energy dispersion component (γₛ^{d}) and a polar component (γₛ^{h}) from Owens equation obtained by expanding Fowkes equation provided in Formula B′ and Young equation, and a sum of the both is set as surface energy (γₛ).

γ_{L}(1+cos θ)=2(γ_{S}^{d}γ_{L}^{d})^{1/2}+2(γ_{S}^{h}γ_{L}^{h})^{1/2} (B′)

γ_{S}=γ_{S}^{d}+γ_{S}^{h}

γ_{L}: Surface tension of contact medium

γ_{L}^{d}: Surface tension dispersion component of contact medium

γ_{L}^{h}: Surface tension polar component of contact medium

γ_{S}: Surface energy

γ_{S}^{d}: Surface energy dispersion component

γ_{S}^{h}: Surface energy polar component

θ: Contact angle of contact medium with respect to surface of polymer film

According to the present invention, as a surface energy, values measured in advance can be employed for various polymers.

Surface energy of a representative polymer is as below.

Poly(t-butylstyrene): 29.7 mN/m², poly(2-ethylhexyl acrylate): 31.1 mN/m², poly(α-methylstyrene): 33.7 mN/m², poly(vinyl stearate): 35.6 mN/m², poly(isobutyl methacrylate): 35.8 mN/m², and polystyrene: 38.4 mN/m².

A weight-average molecular weight of the polymer is not particularly limited, but is preferably 1,000 to 20,000,000, more preferably 3,000 to 10,000,000, and even more preferably 5,000 to 6,000,000.

A weight-average molecular weight according to the present invention is a weight-average molecular weight in terms of polystyrene, which is measured by gel permeation chromatography (GPC) in a case where tetrahydrofuran (THF) is used as a solvent.

In the polymer, the solubility to Component C is preferably higher than that of Component A. In this aspect, mobility and heat stability of the obtained organic semiconductor film and the obtained organic semiconductor element are excellent.

The content of the polymer in the composition for forming an organic semiconductor film according to the present invention is preferably 1 to 10,000 parts by mass, more preferably 10 to 1,000 parts by mass, even more preferably 25 to 400 parts by mass, and most preferably 50 to 200 parts by mass with respect to 100 parts by mass of the content of Component A. If the content is in the range described above, mobility of the obtained organic semiconductor and evenness of the film are excellent.

Component C: Solvent of which boiling point is 150° C. or higher, and SP value is 18 to 23

The composition for forming an organic semiconductor film according to the present invention contains a solvent (hereinafter, referred to as a specific solvent) of which a boiling point is 150° C. or higher, and an SP value is 18 to 23 as Component C.

In the specific solvent, a boiling point is 150° C. or higher. If the boiling point is 150° C. or higher, preservation stability of the composition for forming an organic semiconductor film is excellent, and the specific solvent can be suitably used for ink jet printing and/or flexographic printing.

The boiling point of the specific solvent is preferably 165° C. or higher, more preferably 175° C. or higher, and even more preferably 200° C. or higher. In view of removing the solvent, the boiling point of the specific solvent is preferably 300° C. or lower, more preferably 280° C. or lower, and even more preferably 250° C. or lower.

The SP value (MPa^{1/2}) of the specific solvent is 18 to 23. If the SP value is in the range described above, solubility of Component A is excellent. If the specific solvent is used together with Component D, the organic semiconductor crystal growth is stabilized, and, even in an organic semiconductor having an asymmetric side chain, mobility is high and variation in mobility is suppressed.

The SP value of the specific solvent is preferably 18.5 to 22.5 and more preferably 19 to 22.

According to the present invention, the “SP value” means “the value of the solubility parameter”. The SP value according to the present invention is a Hansen solubility parameter by an equation explained in Hansen solubility parameter: A User's Handbook, Second Edition, C. M. Hansen (2007), Taylor and Francis Group, LLC (HSPiP manual), and a value obtained by calculating an SP value in the following equation by using “Practice Hansen solubility parameter HSPiP Third edition” (Software version 4.0.05) is used.

(SP value)²=(δHD)²+(δHp)²+(δHh)²

Hd: Dispersion contribution

Hp: Polar contribution

Hh: Hydrogen bond contribution

According to the present invention, the specific solvent preferably contains a halogen atom. Examples of the halogen atom include a fluorine atom, a chlorine atom, a bromine atom, and an iodine atom. A fluorine atom, a chlorine atom, and a bromine atom are preferable, a chlorine atom and a bromine atom are more preferable, and a chlorine atom is even more preferable.

It is preferable that the specific solvent contains a halogen atom, since solubility of an organic semiconductor is high, wettability to substrate is satisfactory, and reduction of coating variation is excellent.

The specific solvent is preferably an aromatic solvent. The aromatic solvent may be an aromatic hydrocarbon solvent, and may be a hetero aromatic solvent having a hetero atom. It is preferable that the specific solvent is an aromatic solvent, since solubility of Component A is excellent.

The specific solvent is an aromatic solvent and particularly preferably has a halogen atom.

According to the present invention, the solvent preferable as Component C is provided below together with a boiling point and an SP value.

Tetralin (boiling point: 208° C., SP value: 19.6), anisole (boiling point: 154° C., SP value: 19.7), 1-methylnaphthalene (boiling point: 241° C., SP value: 20.0), 1,2-dichlorobenzene (boiling point: 181° C., SP value: 20.1), 1-fluoronaphthalene (boiling point: 212° C., SP value: 20.3), 2,5-dichlorothiophene (boiling point: 162° C., SP value: 20.7), and 2,5-dibromothiophene (boiling point: 211° C., SP value: 22.0).

Among these, tetralin, anisole, 1-fluoronaphthalene, 1,2-dichlorobenzene, and 2,5-dibromothiophene are more preferable, and 1-fluoronaphthalene, 1,2-dichlorobenzene, and 2,5-dibromothiophene are even more preferable.

Component C may be used singly or two or more types thereof may be used in combination.

Component C can be suitably added such that a content of Component A in the composition for forming an organic semiconductor film and a total solid content below is in a desired range.

According to the present invention, the composition for forming an organic semiconductor film may contain a solvent other than a specific solvent as a solvent. However, when a total content of the solvent is 100 parts by mass, a content of the specific solvent is preferably 50 parts by mass or greater, more preferably 70 parts by mass or greater, even more preferably 90 parts by mass or greater. It is particularly preferable that all of the solvent contained in the composition for forming an organic semiconductor film is a specific solvent.

Component D: Silicone Compound having Structure Represented by Formula D-1

The composition for forming an organic semiconductor film according to the present invention contains a silicone compound having a structure represented by Formula D-1, as Component D.

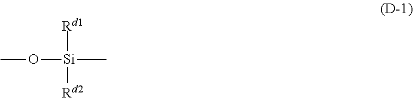

In Formula D-1, R^{d1} and R^{d2} each independently represent a monovalent hydrocarbon group not including an ether bond.

In Formula D-1, if R^{d1} and/or R^{d2} contains an ether bond, R^{d1} and/or R^{d2} is trapped, and thus mobility becomes low.

In Formula D-1, R^{d1} and R^{d2} preferably represents an alkyl group or an aryl group as a monovalent hydrocarbon group.

The alkyl group is preferably an alkyl group having 1 to 20 carbon atoms, more preferably an alkyl group having 1 to 12 carbon atoms, even more preferably an alkyl group having 1 to 6 carbon atoms, and particularly preferably an alkyl group having 1 to 4 carbon atoms. The alkyl group has any one of a linear shape, a branched shape, and a cyclic shape, and is preferably a linear shape or a branched shape.

The aryl group is preferably an aryl group having 6 to 20 carbon atoms, more preferably an aryl group having 6 to 14 carbon atoms, even more preferably an aryl group having 6 to 10 carbon atoms, and particularly preferably a phenyl group.

At least one of d^{d1} or R^{d2} is preferably an alkyl group having 2 to 18 carbon atoms or an alkenyl group having 2 to 18 carbon atoms. The alkyl group and alkenyl group may have a substituent, and examples of the substituent include an aryl group.

At least one of d^{d1} or R^{d2} is preferably an aralkyl group (an alkyl group substituted with an aryl group). The aryl group included in the aralkyl group is preferably an aryl group having 6 to 20 carbon atoms, more preferably an aryl group having 6 to 14 carbon atoms, even more preferably an aryl group having 6 to 10 carbon atoms, and particularly preferably a phenyl group. The alkylene group included in the aralkyl group is preferably an alkylene group having 1 to 20 carbon atoms, more preferably an alkylene group having 2 to 18 carbon atoms, and particularly preferably an alkylene group having 2 to 12 carbon atoms.

Component D is preferably a compound having a polysiloxane structure, and is preferably a silicone compound having a polysiloxane structure having a structure represented by Formula D-1 at at least a portion of repeating units.

Component D is preferably a silicone compound having a structure represented by Formula D-2.

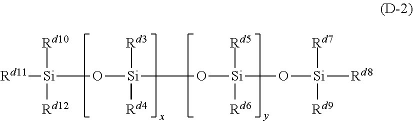

In Formula D-2, R^{d3}, R^{d4}, R^{d5}, as and R^{d7} to R^{d12} each independently represent an unsubstituted alkyl group, an unsubstituted aryl group, or an alkyl group substituted with a halogen atom, and R^{d6} represents a monovalent hydrocarbon group not including an ether bond. x and y each represent an arbitrary integer.

In Formula D-2, an unsubstituted alkyl group represented by R^{d3}, R^{d4}, R^{d5}, or R^{d7} to R¹² preferably has 1 to 20 carbon atoms, more preferably has 1 to 12 carbon atoms, and even more preferably has 1 to 6 carbon atoms.

In Formula D-2, an unsubstituted aryl group represented by R^{d3}, R^{d4}, R^{d5}, or R^{d7} to R^{d12} preferably has 6 to 20 carbon atoms, more preferably has 6 to 14 carbon atoms, even more preferably has 6 to 10 carbon atoms, and particularly preferably a phenyl group.

The alkyl group substituted with a halogen atom preferably has 1 to 20 carbon atoms, more preferably has 1 to 12 carbon atoms, and even more preferably has 1 to 6 carbon atoms. Examples of the halogen atom include a fluorine atom, a chlorine atom, a bromine atom, and an iodine atom, and a fluorine atom is preferable.

A plurality of R^{d3}'s and R^{d4}'s may be identical to or different from each other.

In Formula D-2, R^{d6} is preferably an alkyl group having 2 to 32 carbon atoms or an alkenyl group having 2 to 32 carbon atoms, more preferably an alkyl group having 2 to 24 carbon atoms or an alkenyl group having 2 to 24 carbon atoms, and even more preferably an alkyl group having 2 to 18 carbon atoms or an alkenyl group having 2 to 18 carbon atoms. R^{d6} may be any one of a linear shape, a branched shape, and a cyclic shape. However, in a case where R^{d6} is an unsubstituted alkyl group, the alkyl group is preferably a linear alkyl group having 2 to 32 carbon atoms, more preferably a linear alkyl group having 8 to 18 carbon atoms, and even more preferably a linear alkyl group having 12 to 18 carbon atoms.

The alkyl group is preferably an aralkyl group in which an alkyl group is further substituted with an aryl group. In a case where R^{d6} is an aralkyl group, the aralkyl group is preferably an aralkyl group having 7 to 32 carbon atoms, more preferably an aralkyl group having 7 to 18 carbon atoms, and even more preferably —CH₂—CH(CH₃)—C₆H₅.

Component D is preferably a silicone compound such as polydimethylsiloxane, poly(dimethylsiloxane-co-methylphenylsiloxane), poly(dimethylsiloxane-co-diphenylsiloxane), and poly(dimethylsiloxane-co-methylalkylsiloxane) and an aralkyl modified silicone compound in which a portion of a methyl group, a phenyl group, and an alkyl group which is a side chain bonded to a silicon atom of these silicone compounds is substituted with an aralkyl group and more preferably an aralkyl modified silicone compound in which a portion of a methyl group, a phenyl group, and an alkyl group which is a side chain bonded to a silicon atom of the silicone compound is modified with an aralkyl group.

Viscosity of Component D at 25° C. is preferably 10 to 10,000 mPa·s, more preferably 50 to 5,000 mPa·s, and even more preferably 80 to 1,000 mPa·s. It is preferable that the viscosity of Component D is in the range described above, since mobility of the obtained organic semiconductor is high and variation in the mobility is suppressed.

As Component D, commercially available products may be used, and a commercially available product from Shin-Etsu Chemical Co., Ltd., BYK Additives & Instruments, and the like may be appropriately selected to be used. Specific examples thereof include KF-96-100cs (manufactured by Shin-Etsu Chemical Co., Ltd., polydimethylsiloxane), KF-410 (manufactured by Shin-Etsu Chemical Co., Ltd., aralkyl modified polydimethylsiloxane), KF-412 (manufactured by Shin-Etsu Chemical Co., Ltd., long chain alkyl modified polydimethylsiloxane), BYK-322, BYK-323 (above are manufactured by BYK Additives & Instruments, aralkyl modified polymethylalkylsiloxane). Among these, KF-410, BYK-322, and BYK-323 are preferable.

The content of Component D is not particularly limited. However, the content thereof is preferably 0.1 to 50 parts by mass, more preferably 0.3 to 30 parts by mass, and even more preferably 0.5 to 25 parts by mass with respect to 100 parts by mass of Component A.

The content of Component D is preferably 0.01 to 20 mass %, more preferably 0.05 to 10 mass %, and even more preferably 0.1 to 5 mass % with respect to a solid content of the composition for forming an organic semiconductor film according to the present invention.

<Other Components>

The composition for forming an organic semiconductor film according to the present invention may include other components in addition to Components A to D.

As the other components, well-known additives may be used.

A concentration of a total solid content of the composition for forming an organic semiconductor film according to the present invention is preferably 1.5 mass % or greater. The solid content is an amount of the component excluding a volatile component such as a solvent. That is, a concentration of a total solid content including Components A, B, and D is preferably 1.5 mass % or greater. It is preferable that the concentration of the solid content is 1.5 mass % or greater, since film formability by various printing methods becomes excellent.

The concentration of the total solid content in the composition for forming an organic semiconductor film is more preferably 2 mass % or greater and even more preferably 3 mass % or greater. The upper limit thereof is not limited. However, in view of solubility of Component A, the concentration is preferably 20 mass % or less, more preferably 15 mass % or less, and even more preferably 10 mass % or less. If concentration is in the range described above, the preservation stability and the film formability are excellent, and mobility of the obtained organic semiconductor is excellent.

The viscosity of the composition for forming an organic semiconductor film according to the present invention is not particularly limited. However, in view of excellent various high water resistance, particularly, high ink jet water resistance and high flexographic water resistance, the viscosity is preferably 3 to 100 mPa·s, more preferably 5 to 50 mPa·s, and even more preferably 9 to 40 mPa·s. The viscosity according to the present invention is viscosity at 25° C.

As a measuring method of viscosity, a measuring method in conformity with JIS Z8803 is preferable.

The method of manufacturing a composition for forming an organic semiconductor film according to the present invention is not particularly limited, and well-known methods can be employed. For example, predetermined amounts of Components A, B, and D in Component C are added, and a stirring treatment is suitably performed, so as to obtain a desired composition. Components A, B, and D may be simultaneously or sequentially added so as to suitably manufacture the composition.

(Organic Semiconductor Film and Organic Semiconductor Element)

The organic semiconductor film according to the present invention is manufactured by using the composition for forming an organic semiconductor film according to the present invention, and the organic semiconductor element according to the present invention is manufactured by using the composition for forming an organic semiconductor film according to the present invention.

A method of manufacturing an organic semiconductor film or an organic semiconductor element by using the composition for forming an organic semiconductor film of the present invention is not particularly limited, and known methods can be adopted. Examples thereof include a method for manufacturing an organic semiconductor film or an organic semiconductor element by applying the composition onto a predetermined base material and performing a drying treatment, if necessary.

The method of applying the composition onto a base material is not particularly limited, and known methods can be adopted. Examples thereof include an ink jet printing method, a flexographic printing method, a bar coating method, a spin coating method, a knife coating method, a doctor blade method, a drop cast method, and the like. Among these, an ink jet printing method, a flexographic printing method, a spin coating method, and a drop cast method are preferable, and an ink jet printing method and a flexographic printing method are particularly preferable.

Preferred examples of the flexographic printing method include an aspect in which a photosensitive resin plate is used as a flexographic printing plate. By printing the composition onto a substrate according to the aspect, a pattern can be easily formed.

Among the methods present, the method of manufacturing an organic semiconductor film and the method of manufacturing an organic semiconductor element according to the present invention preferably include an applying step of applying the composition for forming an organic semiconductor film of the present invention on a substrate and a removing step of removing the solvent from the applied composition.

The drying treatment in the removing step is a treatment performed if necessary, and according to the type of the specific compound and the solvent. In view of further improving mobility and heat stability of the obtained organic semiconductor and improving productivity, a heating temperature is preferably 30° C. to 150° C. and more preferably 40° C. to 100° C., and a heating time is preferably 1 to 300 minutes and more preferably 10 to 120 minutes.

A film thickness of the organic semiconductor film according to the present invention is not particularly limited. In view of mobility and heat stability of the obtained organic semiconductor, the film thickness is preferably 5 to 500 nm and more preferably 20 to 200 nm.

The organic semiconductor film according to the present invention can be suitably used in an organic semiconductor element, and can be particularly preferably used in an organic transistor (organic thin film transistor).

The organic semiconductor film according to the present invention can be suitably manufactured by using the composition for forming an organic semiconductor film according to the present invention.

<Organic Semiconductor Element>

The organic semiconductor element is not particularly limited, but is preferably an organic semiconductor element having 2 to 5 terminals, and more preferably an organic semiconductor element having 2 or 3 terminals.

It is preferable that the organic semiconductor element is an element that does not use a photoelectric function.

The organic semiconductor element according to the present invention is preferably a non-luminous organic semiconductor element.

Examples of a 2-terminal element include a rectifier diode, a constant voltage diode, a PIN diode, a Schottky barrier diode, a surge protection diode, a diac, a varistor, a tunnel diode, and the like.

Examples of a 3-terminal element include a bipolar transistor, a Darlington transistor, a field effect transistor, insulated gate bipolar transistor, a uni-junction transistor, a static induction transistor, a gate turn-off thyristor, a triac, a static induction thyristor, and the like.

Among these, a rectifier diode and transistors are preferable, and a field effect transistor is more preferable.

An aspect of the organic thin film transistor of the present invention will be described with reference to a drawing.

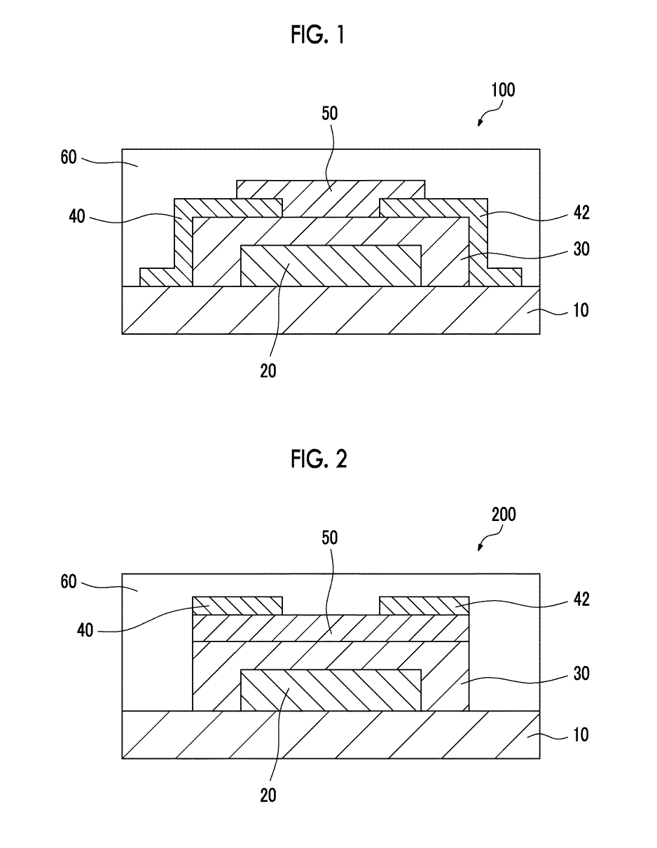

FIG. 1 is a schematic cross-sectional view of an aspect of an organic semiconductor element (organic thin film transistor (TFT)) of the present invention.

In FIG. 1, an organic thin film transistor 100 comprises a substrate 10, a gate electrode 20 disposed on the substrate 10, a gate insulating film 30 covering the gate electrode 20, a source electrode 40 and a drain electrode 42 which contact a surface of the gate insulating film 30 that is on the side opposite to the gate electrode 20 side, an organic semiconductor film 50 covering a surface of the gate insulating film 30 between the source electrode 40 and the drain electrode 42, and a sealing layer 60 covering each member. The organic thin film transistor 100 is a bottom gate-bottom contact type organic thin film transistor.

In FIG. 1, the organic semiconductor film 50 corresponds to a film formed of the composition described above.

Hereinafter, the substrate, the gate electrode, the gate insulating film, the source electrode, the drain electrode, the organic semiconductor film, the sealing layer, the polymer layer, and methods for forming each of these will be specifically described.

[Substrate]

The substrate plays a role of supporting the gate electrode, the source electrode, the drain electrode, and the like which will be described later.

The type of the substrate is not particularly limited, and examples thereof include a plastic substrate, a glass substrate, a ceramic substrate, and the like. Among these, in view of applicability to each device and costs, a glass substrate or a plastic substrate is preferable.

Examples of materials of the plastic substrate include a thermosetting resin (for example, an epoxy resin, a phenol resin, a polyimide resin, or a polyester resin (for example, polyethylene terephthalate (PET) or polyethylene naphthalate (PEN)) and a thermoplastic resin (for example, a phenoxy resin, a polyethersulfone, polysulfone, or polyphenylene sulfone).

Examples of materials of the ceramic substrate include alumina, aluminum nitride, zirconia, silicon, silicon nitride, silicon carbide, and the like.

Examples of materials of the glass substrate include soda lime glass, potash glass, borosilicate glass, quartz glass, aluminosilicate glass, lead glass, and the like.

[Gate Electrode, Source Electrode, and Drain Electrode]

Examples of materials of the gate electrode, the source electrode, and the drain electrode include a metal such as gold (Au), silver, aluminum (Al), copper, chromium, nickel, cobalt, titanium, platinum, tantalum, magnesium, calcium, barium, or sodium; a conductive oxide such as InO₂, SnO₂, or indium tin oxide (ITO); a conductive polymer such as polyaniline, polypyrrole, polythiophene, polyacetylene, or polydiacetylene; a semiconductor such as silicon, germanium, or gallium arsenide; a carbon material such as fullerene, carbon nanotubes, or graphite; and the like. Among these, a metal is preferable, and silver and aluminum are more preferable.

A thickness of each of the gate electrode, the source electrode, and the drain electrode is not particularly limited, but is preferably 20 to 200 nm.

A method of forming the gate electrode, the source electrode, and the drain electrode is not particularly limited, but examples thereof include a method of vacuum vapor-depositing or sputtering an electrode material onto a substrate, a method of coating a substrate with a composition for forming an electrode, a method of printing a composition for forming an electrode onto a substrate, and the like. Furthermore, in a case where the electrode is patterned, examples of the patterning method include photolithography; a printing method such as ink jet printing, screen printing, offset printing, or relief printing; a mask vapor deposition method; and the like.

[Gate Insulating Film]

Examples of materials of the gate insulating film include a polymer such as polymethyl methacrylate, polystyrene, polyvinylphenol, polyimide, polycarbonate, polyester, polyvinylalcohol, polyvinyl acetate, polyurethane, polysulfone, polybenzoxazole, polysilsesquioxane, an epoxy resin, or a phenol resin; an oxide such as silicon dioxide, aluminum oxide, or titanium oxide; a nitride such as silicon nitride; and the like. Among these materials, in view of the compatibility with the organic semiconductor film, a polymer is preferable.

In a case where a polymer is used as the material of the gate insulating film, it is preferable to use a cross-linking agent (for example, melamine) in combination. If the cross-linking agent is used in combination, the polymer is cross-linked, and durability of the formed gate insulating film is improved.

A film thickness of the gate insulating film is not particularly limited, but is preferably 100 to 1,000 nm.

A method of forming the gate insulating film is not particularly limited, but examples thereof include a method of coating a substrate, on which the gate electrode is formed, with a composition for forming a gate insulating film, a method of vapor-depositing or sputtering the material of the gate insulating film onto a substrate on which the gate electrode is formed, and the like. A method of coating the aforementioned substrate with the composition for forming a gate insulating film is not particularly limited, and it is possible to use a known method (a bar coating method, a spin coating method, a knife coating method, or a doctor blade method).

In a case where the gate insulating film is formed by coating the substrate with the composition for forming a gate insulating film, for the purpose of removing the solvent, causing cross-linking, or the like, the composition may be heated (baked) after coating.

[Organic Semiconductor Film]

The organic semiconductor film according to the present invention is a film formed with the composition for forming the organic semiconductor film according to the present invention.

The method of forming an organic semiconductor film is not particularly limited, and it is possible to form a desired organic semiconductor film by applying the aforementioned composition to a source electrode, a drain electrode, and a gate insulating film and performing a dry treatment, if necessary.

[Polymer Layer]

The organic semiconductor element of the present invention preferably has a layer of the aforementioned polymer between the aforementioned organic semiconductor film and an insulating film, and more preferably has a layer of the aforementioned polymer between the aforementioned organic semiconductor film and the gate insulating film. A film thickness of the polymer layer is not particularly limited, but is preferably 20 to 500 nm. The polymer layer should be a layer containing the aforementioned polymer, and is preferably a layer composed of the aforementioned polymer.

A method of forming the polymer layer is not particularly limited, and a known method (a bar coating method, a spin coating method, a knife coating method, a doctor blade method, or an ink jet method) can be used.

In a case where the polymer layer is formed by performing coating by using a composition for forming a polymer layer, for the purpose of removing a solvent, causing cross-linking, or the like, the composition may be heated (baked) after coating.

[Sealing Layer]

In view of durability, the organic semiconductor element of the present invention preferably comprises a sealing layer as an outermost layer. In the sealing layer, a known sealant can be used.

A thickness of the sealing layer is not particularly limited, but is preferably 0.2 to 10 μm.

A method of forming the sealing layer is not particularly limited, but examples thereof include a method of coating a substrate, on which the gate electrode, the gate insulating film, the source electrode, the drain electrode, and the organic semiconductor film are formed, with a composition for forming a sealing layer, and the like. Specific examples of the method of coating the substrate with the composition for forming a sealing layer are the same as the examples of the method of coating the substrate with the composition for forming a gate insulating film. In a case where the sealing layer is formed by coating the substrate with the composition for forming a sealing layer, for the purpose of removing the solvent, causing cross-linking, or the like, the composition may be heated (baked) after coating.

FIG. 2 is a schematic cross-sectional view of another aspect of the organic semiconductor element (organic thin film transistor) of the present invention.

In FIG. 2, an organic thin film transistor 200 comprises the substrate 10, the gate electrode 20 disposed on the substrate 10, the gate insulating film 30 covering the gate electrode 20, the organic semiconductor film 50 disposed on the gate insulating film 30, the source electrode 40 and the drain electrode 42 disposed on the organic semiconductor film 50, and the sealing layer 60 covering each member. Herein, the source electrode 40 and the drain electrode 42 are formed using the aforementioned composition of the present invention. The organic thin film transistor 200 is a bottom gate-top contact type organic thin film transistor.

The substrate, the gate electrode, the gate insulating film, the source electrode, the drain electrode, the organic semiconductor film, the polymer layer, and the sealing layer are as described above.

In FIGS. 1 and 2, the aspects of the bottom gate-bottom contact type organic thin film transistor and the bottom gate-top contact type organic thin film transistor were specifically described. However, the organic semiconductor element of the present invention can also suitably used in a top gate-bottom contact type organic thin film transistor and a top gate-top contact type organic thin film transistor.

The organic thin film transistor described above can be suitably used for electronic paper and a display device.

### EXAMPLES

Hereinafter, the present invention will be more specifically described based on examples. The materials and the amount thereof used, the proportion of the materials, the content and procedure of treatments, and the like described in the following examples can be suitably changed within a scope that does not depart from the gist of the present invention. Accordingly, the scope of the present invention is not limited to the following specific examples. Herein, unless otherwise specified, “part” and “%” are based on mass.

(Organic Semiconductor)

Structures of Compounds 1 to 15 and Comparative Compounds 1 to 4 used in an organic semiconductor layer are provided below.

Compounds 1 to 15 and Comparative Compounds 1 to 4 were synthesized with reference to well-known synthesis method. Specifically, Compound 1 was synthesized with reference to methods described in JP2009-275032A, Compound 2 was synthesized with reference to methods disclosed in JP2011-32268A, Compounds 3 to 5 and Comparative Compounds 1 and 2 were synthesized with reference to methods disclosed in JP2009-54810A, JP2011-526588A, and JP2012-209329A, Compound 6 was synthesized with reference to methods disclosed in Scientific Report, 2014, 4, 5048., Compound 7 was synthesized with reference to methods disclosed in JP2013-540697A, Compound 8 was synthesized with reference to methods disclosed in JP2009-218333A, Compounds 9 to 11 and Comparative Compounds 3 and 4 were synthesized with reference to methods disclosed in US2008/0142792A, Compound 12 was synthesized with reference to methods disclosed in WO2014/156773A, Compound 13 was synthesized with reference to methods disclosed in W02010/098372A, Compound 14 was synthesized with reference to methods disclosed in Adv. Mater., 2014, 26, 4546., and Compound 15 was synthesized with reference to methods disclosed in JP2010-6794A.

It was confirmed that purity (absorption intensity area ratio at 254 nm) of all of the compounds was 99.8% or greater by high performance liquid chromatography (manufactured by Tosoh Corporation, TSK gel ODS-100Z). The structure was identified by ¹H-NMR.

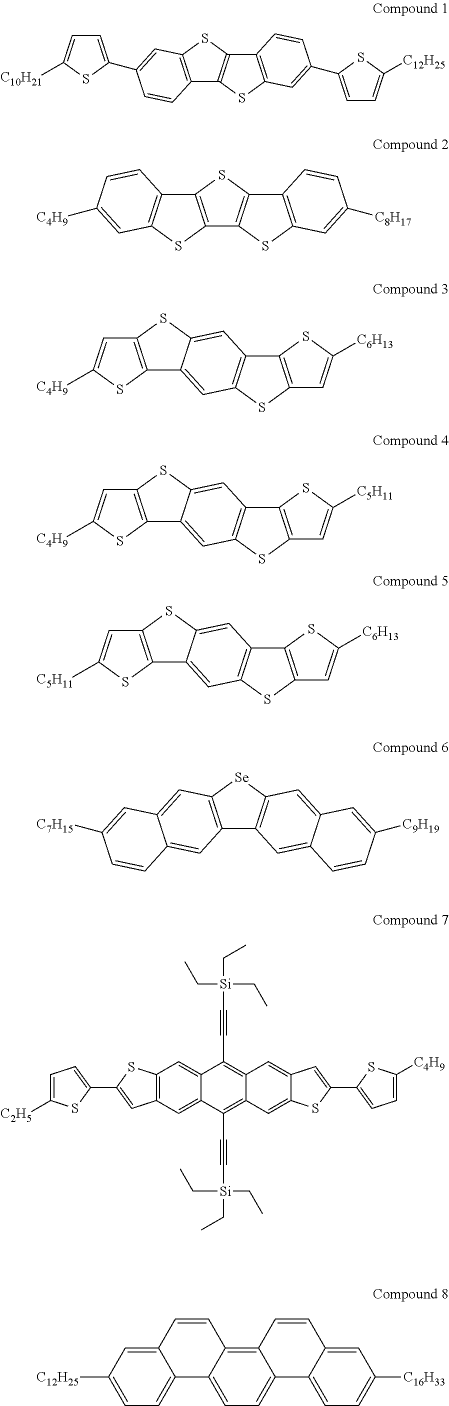

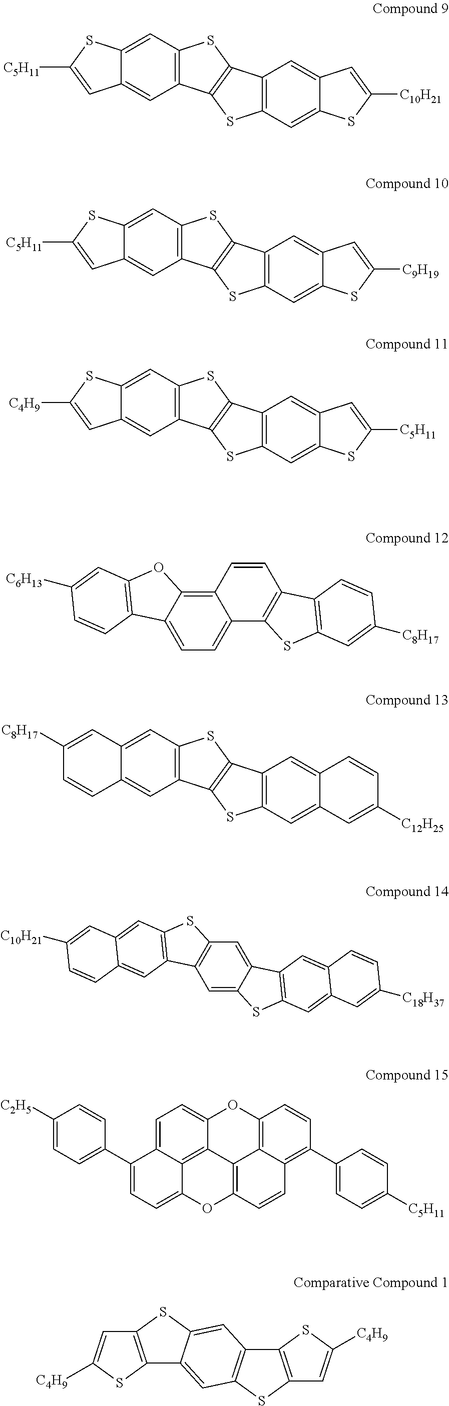

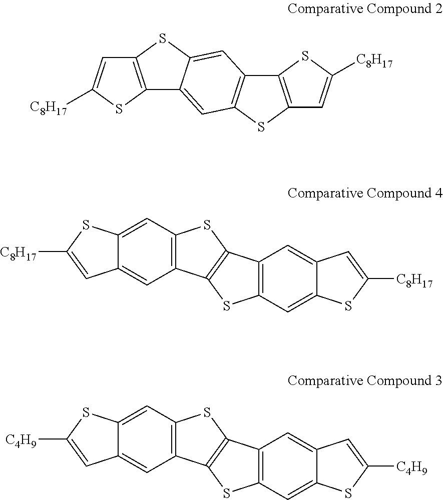

(Solvent)

Solvents used in examples and comparative examples are provided below. Tetralin (boiling point: 208° C., SP value: 19.6, manufactured by Sigma-Aldrich Co., Llc.)

Anisole (boiling point: 154° C., SP value: 19.7, manufactured by Sigma-Aldrich Co., Llc.)

1,2-Dichlorobenzene (boiling point: 181° C., SP value: 20.1, manufactured by Sigma-Aldrich Co., Llc.)

2,5-Dibromothiophene (boiling point: 211° C., SP value: 22.0, manufactured by Sigma-Aldrich Co., Llc.)

Cis-decalin (comparative example) (boiling point: 196° C., SP value: 16.8, manufactured by Sigma-Aldrich Co., Llc.)

m-Xylene (comparative example) (boiling point: 139° C., SP value: 18.2, manufactured by Sigma-Aldrich Co., Llc.)

DMSO (comparative example) (dimethylsulfoxide, boiling point: 189° C., SP value: 23.6, manufactured by Sigma-Aldrich Co., Llc.)

(Polymer)

Polymers used in examples and comparative examples are provided below.

PαMS (poly(a-methyl styrene), weight-average molecular weight: 400,000, surface energy: 33.7 mN/m², manufactured by Sigma-Aldrich Co., Llc.)

PS (polystyrene, weight-average molecular weight :2,000,000, surface energy: 38.4 mN/m², manufactured by Sigma-Aldrich Co., Llc.)

EP65 (ethylene propylene rubber, surface energy: 31.0 mN/m², manufactured by JSR Corporation)

(Silicone Compound) KF-410 (aralkyl modified polydimethylsiloxane (a portion of R^{d1} and R^{d2} is modified with a methyl styryl group (—CH₂—CH(CH₃)—C₆H₅)), manufactured by Shin-Etsu Chemical Co., Ltd.)

KF-412 (Long chain alkyl-modified polydimethylsiloxane, manufactured by Shin-Etsu Chemical Co., Ltd.)

KF-96-100cs (polydimethylsiloxane, weight-average molecular weight: 5,000 to 6,000, manufactured by Shin-Etsu Chemical Co., Ltd.)

BYK-322 (aralkyl modified polymethylalkylsiloxane, manufactured by BYK Additives & Instruments)

BYK-323 (aralkyl modified polymethylalkylsiloxane, manufactured by BYK Additives & Instruments)

KF-353 (comparative example) (polyether-modified polydimethylsiloxane, manufactured by Shin-Etsu Chemical Co., Ltd.)

F-444 (comparative example) (Megaface F444, fluorine-based surfactant, manufactured by DIC Corporation)

F-553 (comparative example) (Megaface F553, fluorine-based surfactant, manufactured by DIC Corporation)

BYK-307 (comparative example) (polyether-modified polydimethylsiloxane, manufactured by BYK Additives & Instruments)

(Preparation of Composition for Forming Organic Semiconductor Film)

The organic semiconductor compounds/solvents/polymers/silicone compounds presented in Table 1 were dissolved in a solvent such that the content of the organic semiconductor compound became 0.8 mass %, and the content of the silicone compound became 0.05 mass %, a polymer was added such that viscosity became 25 mPa·s at 25° C., weighing was performed with a vial, stirring was performed for 10 minutes by a mix rotter (manufactured by As One Corporation), and filtration was performed with a 0.5 μm membrane filter, so as to obtain the composition for forming an organic semiconductor film.

(Preparation of TFT Element)

In the method described below, a bottom gate-bottom contact TFT element was formed.

<Forming of Gate Electrode>

A wiring pattern having a width of 100 μm and a film thickness of 100 nm was formed on an alkali-free glass substrate (5 cm×5 cm) by ink jet printing using silver nano ink (H-1, manufactured by Mitsubishi Materials Corporation) and DMP2831 (1 pico-liter head), and then baking was performed under the atmosphere on a hot plate at 200° C. for 90 minutes so as to form gate electrode wiring.

<Forming of Gate Insulating Film>

5 parts by weight of polyvinylphenol (weight-average molecular weight: 25,000, manufactured by Sigma-Aldrich Co., Llc.), 5 parts by weight of melamine, and 90 parts by weight of polyethylene glycol monomethyl ether acetate were stirred and mixed, filtration was performed with a 0.2 μm membrane filter, so as to prepare a solution. The obtained solution was added dropwise on a glass substrate on which the gate electrode was prepared, coating was performed by spin coating (1,000 rpm, for 120 seconds), and heating was performed at 150° C./30 minutes, so as to form a gate insulating film.

<Forming of SD Electrode>

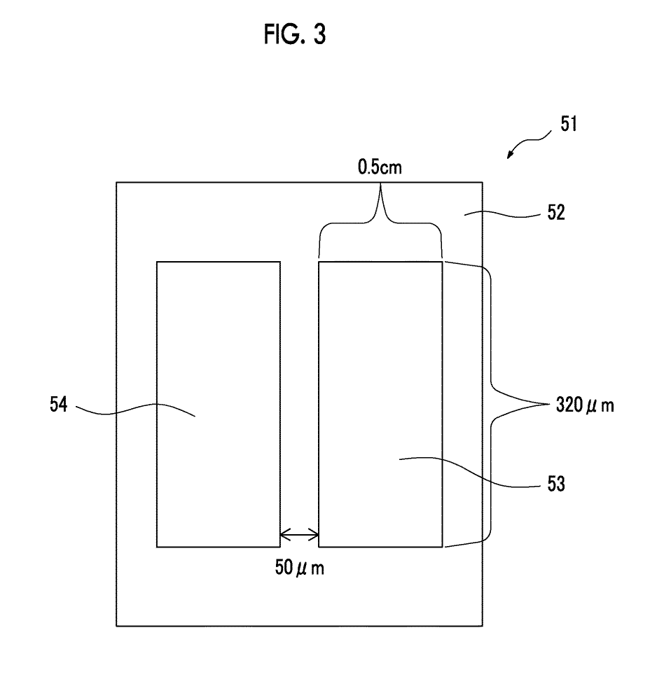

A metal mask having a plurality of patterns illustrated in FIG. 3 was mounted on the center of the substrate coated with the insulating film, irradiation was performed for 30 minutes with UV ozone, and an opening portion of the mask was modified to a hydrophilically treated surface. Source drain electrode patterns having a channel length of 50 μm, and a channel width of 320 μm were formed at the edge part of the modified portion by ink jet printing using DMP2831 (1 pico-liter head). The obtained substrate was baked under the N₂ atmosphere (in a glove box in an environment of oxygen concentration of 20 ppm or less) on a hot plate at 200° C. for 90 minutes, so as to form a copper electrode having a film thickness of 200 nm.

The substrate on which the source drain electrode was formed was coated with the prepared composition for forming an organic semiconductor film by a flexographic printing method. A flexographic suitability tester F1 (manufactured by IGT Testing Systems) was used as a printing device, and AFP DSH 1.70% (manufactured by Asahi Kasei Corporation)/a solid image was used as a Flexographic resin plate. Printing was performed at the pressure between the plate and the substrate of 60 N and the transportation speed of 0.4 m/seconds, and drying was performed for two hours at 60° C., so as to prepare the organic semiconductor film.

(Performance Evaluation)

(a) Mobility

The following performance evaluation was performed under the atmosphere by using a semiconductor characteristic evaluation device B2900A (manufactured by Agilent Technologies).

A voltage of −60 V was applied between source electrodes and drain electrodes of the respective organic TFT elements, gate voltages were changed in the range of +10 V to −60 V, and carrier mobility μ was calculated by using the following equation representing a drain current I_{d}.

I_{d}=(W/2L)μCᵢ(V_{g}−Vₜₕ)²

In the formula, L represents a gate length, W represents a gate width, Cᵢ represents a capacity per unit area of an insulating layer, V_{g} represents a gate voltage, and Vₜₕ represents a threshold voltage.

As the mobility μ was higher, the mobility μ was more preferable. According to the value of mobility, evaluation was performed in five stages of S to D. The evaluation standard was as below.

S: 0.2 cm²/Vs or greater

A: 0.1 cm²/Vs or greater and less than 0.2 cm²/Vs

B: 0.02 cm²/Vs or greater and less than 0.1 cm²/Vs

C: 0.002 cm²/Vs or greater and less than 0.02 cm²/Vs

D: Less than 0.002 cm²/Vs

(b) Variation in Mobility

In the method above, variation σ with respect to an average value of mobility was evaluated by evaluating five TFT elements. σ was calculated by the following equation.

σ=(Measurement value most separated from average value among measurement values of mobility-average value of mobility)/average value of mobility×100 (%)

S: Variation was less than 20%

A: Variation was 20% or greater and less than 30%

B: Variation was 30% or greater and less than 50%

C: Variation was 50% or greater and less than 100%

D: Variation was 100% or greater

TABLE 1

| | Component A | | | | | | Evaluation | |
|---|---|---|---|---|---|---|---|---|
| | Organic | | | Component B | Component C | Component D | | Variation in |
| | semiconductor | m | n | Polymer | Solvent | Silicone Compound | Mobility | mobility |
| Example 1 | Compound 1 | 10 | 12 | PαMS | Tetralin | KF-410 | A | A |
| Example 2 | Compound 2 | 4 | 8 | PαMS | Tetralin | KF-410 | A | A |
| Example 3 | Compound 3 | 4 | 6 | PαMS | Tetralin | KF-410 | A | A |
| Example 4 | Compound 4 | 4 | 5 | PαMS | Tetralin | KF-410 | S | A |
| Example 5 | Compound 5 | 5 | 6 | PαMS | Tetralin | KF-410 | S | A |
| Example 6 | Compound 6 | 7 | 9 | PαMS | Tetralin | KF-410 | B | A |
| Example 7 | Compound 7 | 2 | 4 | PαMS | Tetralin | KF-410 | B | A |
| Example 8 | Compound 8 | 12 | 16 | PαMS | Tetralin | KF-410 | B | A |
| Example 9 | Compound 9 | 5 | 10 | PαMS | Tetralin | KF-410 | A | A |
| Example 10 | Compound 10 | 5 | 9 | PαMS | Tetralin | KF-410 | A | A |
| Example 11 | Compound 11 | 4 | 5 | PαMS | Tetralin | KF-410 | S | A |
| Example 12 | Compound 12 | 6 | 8 | PαMS | Tetralin | KF-410 | B | A |
| Example 13 | Compound 13 | 8 | 12 | PαMS | Tetralin | KF-410 | A | A |
| Example 14 | Compound 14 | 10 | 18 | PαMS | Tetralin | KF-410 | A | A |
| Example 15 | Compound 15 | 2 | 5 | PαMS | Tetralin | KF-410 | B | B |
| Example 16 | Compound 4 | 4 | 5 | PS | Tetralin | KF-410 | S | A |
| Example 17 | Compound 4 | 4 | 5 | EP65 | Tetralin | KF-410 | S | A |
| Example 18 | Compound 4 | 4 | 5 | PαMS | Tetralin | BYK-322 | S | A |
| Example 19 | Compound 4 | 4 | 5 | PαMS | Tetralin | BYK-323 | S | A |
| Example 20 | Compound 4 | 4 | 5 | PαMS | Tetralin | KF-412 | A | A |
| Example 21 | Compound 4 | 4 | 5 | PαMS | Tetralin | KF-96-100cs | A | A |
| Example 22 | Compound 4 | 4 | 5 | PαMS | Anisole | KF-410 | B | A |
| Example 23 | Compound 4 | 4 | 5 | PαMS | 1,2-Dichlorobenzene | KF-410 | S | S |
| Example 24 | Compound 4 | 4 | 5 | PαMS | 2,5-Dibromothiophene | KF-410 | S | S |
| Comparative | Comparative | 4 | 4 | PαMS | Tetralin | KF-410 | C | B |
| Example 1 | Compound 1 | | | | | | | |
| Comparative | Comparative | 8 | 8 | PαMS | Tetralin | KF-410 | C | B |
| Example 2 | Compound 2 | | | | | | | |
| Comparative | Comparative | 4 | 4 | PαMS | Tetralin | KF-410 | C | B |
| Example 3 | Compound 3 | | | | | | | |
| Comparative | Comparative | 8 | 8 | PαMS | Tetralin | KF-410 | C | B |
| Example 4 | Compound 4 | | | | | | | |
| Comparative | Compound 4 | 4 | 5 | PαMS | Tetralin | — | B | D |
| Example 5 | | | | | | | | |
| Comparative | Compound 4 | 4 | 5 | PαMS | Cis-decalin | KF-410 | D | B |
| Example 6 | | | | | | | | |
| Comparative | Compound 4 | 4 | 5 | PαMS | m-Xylene | KF-410 | D | B |
| Example 7 | | | | | | | | |
| Comparative | Compound 4 | 4 | 5 | PαMS | DMSO | KF-410 | D | B |
| Example 8 | | | | | | | | |
| Comparative | Compound 4 | 4 | 5 | — | Tetralin | KF-410 | D | B |
| Example 9 | | | | | | | | |
| Comparative | Compound 4 | 4 | 5 | PαMS | Tetralin | KF-353 | C | C |
| Example 10 | | | | | | | | |
| Comparative | Compound 4 | 4 | 5 | PαMS | Tetralin | F-444 | C | C |
| Example 11 | | | | | | | | |
| Comparative | Compound 4 | 4 | 5 | PαMS | Tetralin | F-553 | D | B |
| Example 12 | | | | | | | | |
| Comparative | Compound 4 | 4 | 5 | PαMS | Tetralin | BYK-307 | D | B |
| Example 13 | | | | | | | | |

As presented in Table 1, it was found that, in the composition for forming an organic semiconductor film according to the present invention, the obtained organic semiconductor film and the organic semiconductor element had high mobility, and variation in mobility was suppressed.

Meanwhile, it was found that, the composition for forming an organic semiconductor film according to the comparative example, high mobility and suppression of variation in mobility were not able to be compatible with each other.

The same result was able to be obtained, if an evaluation was performed by dissolving the organic semiconductor compound and the silicone compound in the solvent such that the content of the organic semiconductor compound became 0.8 mass % and the content of the silicone compound became 0.05 mass %, adding a polymer such that viscosity at 25° C. became 5 mPa·s, preparing ink, and performing ink jet printing.

### EXPLANATION OF REFERENCES

10: substrate

20: gate electrode

30: gate insulating film

40: source electrode

42: drain electrode

50: organic semiconductor film

51: metal mask

52: mask portion

53,54: opening portion

60: sealing layer

100, 200: organic thin film transistor

What is claimed is:

1. A composition for forming an organic semiconductor film, comprising:
an organic semiconductor represented by Formula A-1;
a polymer;
a solvent having a boiling point of 150° C. or higher and an SP value of 18 to 23; and
a silicone compound having a structure represented by Formula D-1,
CₘH₂ₘ₊₁-L^{a1}-T-L^{a2}-CₙH₂ₙ₊₁ (A-1)
wherein, in Formula A-1, T represents an aromatic hydrocarbon group or a hetero aromatic group which has a fused ring structure of three rings to seven rings, L^{a1} and L^{a2} each independently represent a single bond, a phenylene group, or a thienylene group, and m and n each independently represent an integer of 1 to 20, and m≠n, and 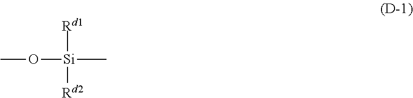
wherein, in Formula D-1, R^{d1} and R^{d2} each independently represent a monovalent hydrocarbon group not including an ether bond.

2. The composition for forming an organic semiconductor film according to claim 1, wherein the compound represented by Formula A-1 comprises a compound represented by Formula A-2, 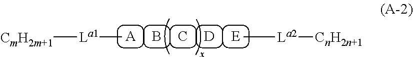
wherein, in Formula A-2, Rings A to E each independently represent a benzene ring or an aromatic hetero ring, L^{a1} and L^{a2} each independently represent a single bond, a phenylene group, or a thienylene group, x represents an integer of 0 to 3, m and n each independently represent an integer of 1 to 20, and m≠n.

3. The composition for forming an organic semiconductor film according to claim 2, wherein, in Formula A-2, symmetry of a fused ring structure formed of Rings A to E is C₂, C₂ᵥ, or C₂ₕ.

4. The composition for forming an organic semiconductor film according to claim 2, wherein, in Formula A-2, Rings A to E each independently represent a benzene ring or a thiophene ring.

5. The composition for forming an organic semiconductor film according to claim 2, wherein, in Formula A-2, Rings A and E are thiophene rings.

6. The composition for forming an organic semiconductor film according to claim 2, wherein, in Formula A-2, x is 1 or 2.

7. The composition for forming an organic semiconductor film according to claim 1, wherein, in Formula A-1, 1≦|m−n|≦4.

8. The composition for forming an organic semiconductor film according to claim 1, wherein, in Formula A-1, |m−n|=1.

9. The composition for forming an organic semiconductor film according to claim 1, wherein, in Formula D-1, at least one of R^{d1} or R^{d2} is an alkyl group having 2 to 18 carbon atoms or an alkenyl group having 2 to 18 carbon atoms.

10. The composition for forming an organic semiconductor film according to claim 1, wherein, in Formula D-1, at least one of R^{d1} or R^{d2} is an aralkyl group.

11. The composition for forming an organic semiconductor film according to claim 1, wherein the solvent contains a halogen atom.

12. The composition for forming an organic semiconductor film according to claim 1, wherein the solvent is an aromatic solvent.

13. The composition for forming an organic semiconductor film according to claim 1, wherein the composition has a viscosity at 25° C. of 5 mPa·s to 40 mPa·s.

14. The composition for forming an organic semiconductor film according to claim 1, which is used for ink jet printing and/or flexographic printing.

15. A method of manufacturing an organic semiconductor film, comprising:
applying the composition for forming an organic semiconductor film according to claim 1 on a substrate; and
drying the composition that has been applied on the substarate.

16. An organic semiconductor film obtained by the method according to claim 15.

17. A method of manufacturing an organic semiconductor element, comprising:
applying the composition for forming an organic semiconductor film according to claim 1 on a substrate; and
drying the composition that has been applied on the substrate.

18. The method of manufacturing an organic semiconductor element according to claim 17, wherein the applying of the composition is performed by ink jet printing or flexographic printing.

19. An organic semiconductor element obtained by the method according to claim 17.
